(19) United States
(12) Patent Application Publication
(10) Pub. No.: US 2012/0038048 A1
(43) Pub. Date: Feb. 16, 2012

(54) STABILIZED NICKEL SILICIDE INTERCONNECTS

(75) Inventors: Cyril Cabral, JR., Mahopac, NY (US); Benjamin Fletcher, New York, NY (US); Christian Lavoie, Pleasantville, NY (US); Zhen Zhang, Ossining, NY (US)

(73) Assignee: INTERNATIONAL BUSINESS MACHINES CORPORATION, Armonk, NY (US)

(21) Appl. No.: 12/854,506

(22) Filed: Aug. 11, 2010

(51) Int. Cl. H01L 23/532; H01L 21/3205

(52) U.S. Cl. 257/741; 438/664; 257/E21.296; 257/E23.157

(57) ABSTRACT

A method of forming nickel monosilicide is provided that includes providing a silicon-containing surface, and ion implanting carbon into the silicon-containing surface.

A nickel-containing layer is formed on the silicon-containing surface. Alloying the nickel-containing surface and the silicon-containing surface layer to provide a nickel monosilicide. The present disclosure also provides a non-agglomerated Ni monosilicide contact that includes a carbon interstitial dopant present in a concentration ranging from 1×10¹⁹ atoms/cm³ to 1×10²¹ atoms/cm³.

### BACKGROUND

The present disclosure is related to interconnects, such as metal semiconductor alloy compound interconnects.

Metal semiconductor alloys, such silicides, are of specific importance to integrated circuits, including complementary metal oxide semiconductor (CMOS) devices, because of the desire to reduce the electrical resistance of the contacts, at the source region, drain region and gate region of the semiconductor devices. Silicide formation typically requires depositing a refractory metal, such as Ni, Co or Ti, onto the surface of a silicon-containing material. Following deposition, the structure is subjected to an annealing step. During annealing, the deposited metal reacts with silicon forming a metal silicide.

### SUMMARY

In one embodiment, the present disclosure provides a method of forming nickel monosilicide that is doped with carbon. The method may include providing a silicon-containing surface and implanting carbon into the silicon-containing surface. A nickel-containing layer is formed on the silicon-containing surface, and the nickel-containing surface and the silicon-containing surface layer are intermixed to provide a nickel monosilicide layer.

In another embodiment, the method may begin with providing a silicon-containing surface and introducing a stabilizing dopant to the silicon-containing surface. A nickel-containing layer is formed on the silicon-containing surface. The nickel-containing surface and the silicon-containing surface layer are intermixed to provide a nickel monosilicide layer. The nickel monosilicide layer may have a resistance of less than 400 Ω/μm for line widths greater than 20 nm when exposed to temperatures of up to 800° C.

In another aspect, the present disclosure provides an electrical device. In one embodiment, the electrical device includes a silicon-containing material, and a non-agglomerated nickel monosilicide contact located on a portion of said silicon-containing material. The non-agglomerated nickel monosilicide contact comprises a carbon interstitial dopant present in a concentration ranging from 1×10¹⁹ atoms/cm³ to 1×10²¹ atoms/cm³.

### DESCRIPTION OF THE DRAWINGS

The following detailed description, given by way of example and not intended to limit the disclosure solely thereto, will best be appreciated in conjunction with the accompanying drawings, wherein like reference numerals denote like elements and parts, in which:

FIG. 1 is a side cross-sectional view depicting a semiconductor device on a semiconductor substrate, in accordance with one embodiment of the present disclosure.

FIG. 2A is a side cross-sectional view depicting forming a silicon-containing layer on an upper surface of a gate structure of the semiconductor device, in accordance with one embodiment of the present disclosure.

FIG. 2B is a side cross-sectional view depicting forming a silicon-containing layer on an upper surface of the gate structure of the semiconductor device, and doping the silicon-containing layer with a stabilizing dopant, in accordance with one embodiment of the present disclosure.

FIG. 3A is a side cross-sectional view depicting patterning and etching the silicon-containing layer depicted in FIG. 2A, and doping the patterned silicon-containing layer with a stabilizing dopant, in accordance with one embodiment of the present disclosure.

FIG. 3B is a side cross-sectional view depicting patterning and etching the silicon-containing layer depicted in FIG. 2B, in accordance with one embodiment of the present disclosure.

FIG. 4 is a side cross-sectional view depicting depositing a nickel-containing layer on the upper surface of the structures depicted in FIGS. 3A and 3B, in accordance with one embodiment of the present disclosure.

FIG. 5 is a side cross-sectional view depicting alloying the nickel-containing layer and the silicon-containing surface to provide a nickel monosilicide layer, in accordance with one embodiment of the present disclosure.

FIG. 6A is a plot of the resistance and the optical scattering of a nickel monosilicide doped with carbon as a function of temperature, in accordance with one embodiment of the present disclosure.

FIG. 6B is a plot of the resistance and the optical scattering of a comparative example of a nickel monosilicide that is not doped with carbon as a function of temperature.

### DETAILED DESCRIPTION

Detailed embodiments of the present disclosure are disclosed herein; however, it is to be understood that the disclosed embodiments are merely illustrative of the present disclosure that may be embodied in various forms. In addition, each of the examples given in connection with the various embodiments of the present disclosure are intended to be illustrative, and not restrictive. Further, the figures are not necessarily to scale, some features may be exaggerated to show details of particular components. Therefore, specific structural and functional details disclosed herein are not to be interpreted as limiting, but merely as a representative basis for teaching one skilled in the art to variously employ the present disclosure.

References in the specification to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described. For purposes of the description hereinafter, the terms “upper”, “lower”, “right”, “left”, “vertical”, “horizontal”, “top”, “bottom”, and derivatives thereof shall relate to the invention, as it is oriented in the drawing figures. The terms “overlying”, “atop”, “positioned on” or “positioned atop” means that a first element, such as a first structure, is present on a second element, such as a second structure, wherein intervening elements, such as an interface structure, e.g. interface layer, may be present between the first element and the second element. The term “direct contact” means that a first element, such as a first structure, and a second element, such as a second structure, are connected without any intermediary conducting, insulating or semiconductor layers at the interface of the two elements.

The present disclosure increases the thermal stability of nickel monosilicide with a stabilizing dopant. In one embodiment, the stabilizing dopant is carbon and the nickel monosilicide provides a contact to an electrical device. The term “electrical devices” as used herein is meant to denote a semiconductor device and/or memory device, as well as resistors, capacitors, inductors and diodes. The contact may be an interconnect line, wherein the interconnect line serves as a metal wiring that carries electrical signals throughout the electrical device.

It has been determined, that the scaling of copper interconnects below the 40 nm in linewidth results in increased resistivity due to scattering, as the dimensions of the linewidth of the interconnects are decreased to below the electron mean free path of copper. The electron mean free path of copper is on the order of 39 nm. The increased resistance results from scattering at the surface and grain boundaries of the copper employed within the interconnect line. Another disadvantage of copper is that with increasing surface area to volume ratios, copper exhibits increased electromigration and stress migration degradation.

The electron mean free path of nickel monosilicide is approximately 10 nm. Therefore, because the mean free path of nickel monosilicide is on the order of 10 nm, the increased resistance that occurs in copper interconnects having line widths of 40 nm or less, does not occur in nickel monosilicide interconnects having line widths of 40 nm or less. Nickel monosilicide also is less susceptible to electromigration than copper. However, nickel monosilicide disadvantageously has a low thermal stability at temperatures close to 600° C. and greater. Specifically, at temperatures of about 600° C. an increase in film resistance reflects a change in morphology of the film (due to aggregation). Therefore, nickel monosilicide (NiSi) has failed to provide suitable resistances for interconnects in structures that require processing temperatures above 600° C. Further, above a temperature of about 750° C., a phase conversion occurs of the nickel monosilicide (NiSi) to nickel disilicide (NiSi₂). The nickel disilicide phase has a higher resistance than the nickel monosilicide phase.

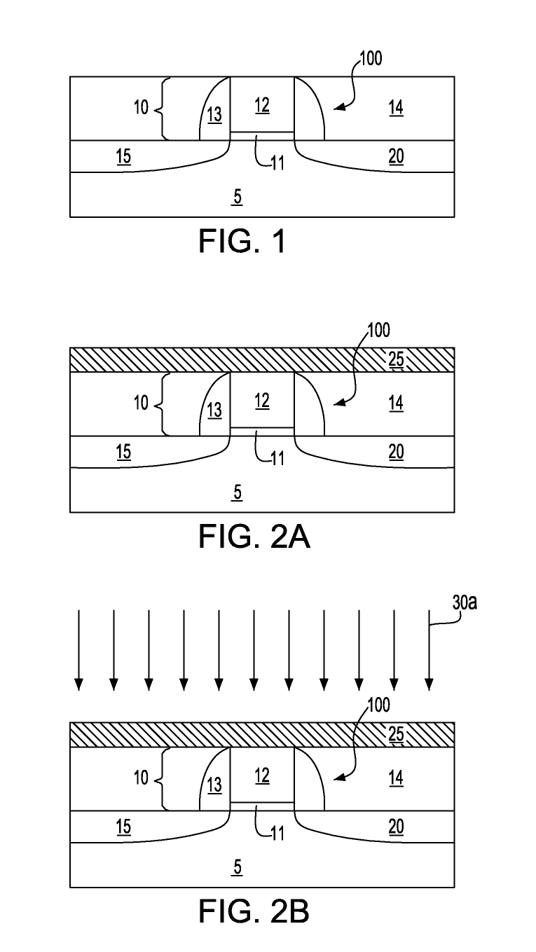

To improve the thermal stability of nickel monosilicide, the present disclosure introduces a stabilizing dopant, e.g., carbon, into the silicon-containing material component of the nickel monosilicide prior to the silicidation reaction. In some embodiments, the stabilizing dopant, such as carbon, also decreases the line edge and surface roughness of the interconnect, which results in decreased resistance when compared to nickel monosilicide that does not include the stabilizing dopant. The method may include providing a silicon-containing surface and implanting a stabilizing dopant, e.g., carbon, into the silicon-containing surface. Forming a nickel-containing layer on the silicon-containing surface, and intermixing the nickel-containing surface and the silicon-containing surface layer to provide a nickel monosilicide layer. FIGS. 1-5 illustrate one embodiment of a method of forming a nickel monosilicide having improved thermal stability. Although FIGS. 1-5 depict forming an interconnect line being formed to the gate structure of a semiconductor device 100, such as a field effect transistor, the nickel monosilicide 50 of the present disclosure may be utilized in any type of contact, i.e., interconnect, to any type of electrical device. Further, in addition to the interconnect line that is formed to the gate structure 10, interconnect lines may be formed to each of the source and drain regions 15, 20.

FIG. 1 depicts a semiconductor device 100 on a semiconductor substrate 5, as used in one embodiment of forming a nickel monosilicide interconnect with increased time thermal stability. The semiconductor substrate 5 may be a bulk-semiconductor substrate. In one example, the bulk-semiconductor substrate may be a silicon-containing material. Illustrative examples of Si-containing materials suitable for the bulk-semiconductor substrate include, but are not limited to, Si, SiGe, SiGeC, SiC, polysilicon, i.e., polySi, epitaxial silicon, i.e., epi-Si, amorphous Si, i.e., α:Si, and multi-layers thereof. Although silicon is the predominantly used semiconductor material in wafer fabrication, alternative semiconductor materials can be employed, such as, but not limited to, germanium, gallium arsenide, gallium nitride, silicon germanium, cadmium telluride and zinc sellenide. Although not depicted in FIG. 1, the semiconductor substrate 5 may also be a semiconductor on insulator (SOI) substrate. A SOI substrate includes a semiconductor-containing layer, such as a silicon-containing layer, atop the surface of a buried dielectric layer, e.g., buried oxide. The semiconductor-containing layer is often referred to as an SOI layer. The SOI substrate also includes a base semiconductor layer that is present under the buried dielectric layer.

Still referring to FIG. 1, a semiconductor device 100 may be formed on the semiconductor substrate 5. A semiconductor device 100 is an intrinsic semiconductor material that has been doped, i.e., into which a doping agent has been introduced, giving it different electrical properties than the intrinsic semiconductor. Doping involves adding dopant atoms to an intrinsic semiconductor, which changes the electron and hole carrier concentrations of the intrinsic semiconductor at thermal equilibrium. Dominant carrier concentration in an extrinsic semiconductor determines the conductivity type of the semiconductor, i.e., p-type or n-type semiconductor.

In the embodiment that is depicted in FIG. 1, the semiconductor device 100 is a field effect transistor. A field effect transistor is one example of a semiconductor device 100 in which output current, i.e., source-drain current, is controlled by the voltage applied to a gate structure 10. A field effect transistor has three terminals, i.e., a gate structure 10, a source region 15 and a drain region 20. The gate structure 10 is the structure used to control output current, i.e., flow of carriers in the channel, of the semiconducting device 100, such as a field effect transistor, through electrical or magnetic fields. The gate structure 10 includes at least one gate dielectric 11, and at least one gate conductor 12.

The gate structure 10 may be formed using deposition, photolithography and selective etching process. In one embodiment, a gate layer stack is by depositing at least one gate dielectric layer on the semiconductor substrate 5, and then depositing at least one gate conductor layer on the at least one gate dielectric layer. The gate layer stack is then patterned and etched to provide the gate structure 10. The gate structure 10 is formed over the channel region of the device.

The gate dielectric layer 11 may be an oxide, nitride and oxynitride material. In one embodiment, the gate dielectric layer 11 may be composed of a high-k dielectric layer, i.e., a dielectric having a dielectric constant that is greater than 4.0, as measured at room temperature. Such higher dielectric constant dielectric materials may include, but are not limited to, hafnium oxides, hafnium silicates, titanium oxides, barium-strontium-titantates (BSTs) and lead-zirconate-titanates (PZTs). In one embodiment, the gate dielectric layer 11 has a thickness ranging from 10 angstroms to 200 angstroms. The gate conductor 12 may be composed of conductive materials including, but not limited to metals, metal alloys, metal nitrides and metal silicides, as well as laminates thereof and composites thereof. In one embodiment, the gate conductor 12 may be any conductive metal including, but not limited to, W, Ni, Ti, Mo, Ta, Cu, Pt, Ag, Au, Ru, Ir, Rh, and Re, and alloys that include at least one of the aforementioned conductive elemental metals. The gate conductor 12 may also comprise doped polysilicon and/or polysilicon-germanium alloy materials (i.e., having a dopant concentration from 1×10¹⁸ dopant atoms per cubic centimeter to 1×10²² dopant atoms per cubic centimeter) and polycide materials (doped polysilicon/metal silicide stack materials). The gate structure 10 may also be formed using replacement gate or dummy gate processing.

The gate structure 10 may further comprise sidewalls spacers 13. The sidewall spacers 13 may be composed of materials including, but not limited to, conductive materials and dielectric materials. The spacer materials may be formed using methods that are generally conventional in the semiconductor fabrication art. The sidewall spacers 13 are often formed by using a blanket layer deposition and anisotropic etchback method. In one embodiment, the sidewall spacer 13 is composed of silicon oxide and has a thickness ranging from 10 angstroms to 1000 angstroms.

The source region 15 is a doped region in the semiconductor device 100, in which majority carriers are flowing into the channel. The drain region 20 is the doped region in semiconductor device 100 located at the end of the channel region, in which carriers are flowing out of the semiconductor device 100 through the drain region. The source and drain regions 15, 20 are formed using ion implantation, in which the width of the sidewall spacers 13 may be selected to position the source and drain regions 15, 20. Doping the source and drain regions 15, 20 with a p-type dopant produces a p-type semiconductor device 100, and doping the source and drain regions 15, 20 with an n-type dopant produces an n-type semiconductor device 100.

Still referring to FIG. 1, an intralevel dielectric 14 may be formed over the semiconductor device 100. The intralevel dielectric 14 may be selected from the group consisting of silicon-containing materials such as SiO₂, Si₃N₄, SiOₓN_{y}, SiC, SiCO, SiCOH, and SiCH compounds, the above-mentioned silicon-containing materials with some or all of the Si replaced by Ge, carbon-doped oxides, inorganic oxides, inorganic polymers, hybrid polymers, organic polymers such as polyamides or SiLK™, other carbon-containing materials, organo-inorganic materials such as spin-on glasses and silsesquioxane-based materials, and diamond-like carbon (DLC, also known as amorphous hydrogenated carbon, α-C:H). Additional choices for the blanket dielectric include any of the aforementioned materials in porous form, or in a form that changes during processing to or from being porous and/or permeable to being non-porous and/or non-permeable. The intralevel dielectric 14 may be formed by various methods including, but not limited to, spinning from solution, spraying from solution, chemical vapor deposition (CVD), plasma enhanced CVD (PECVD), sputter deposition, reactive sputter deposition, ion-beam deposition, and evaporation. The intralevel dielectric 14 may be planarized to expose the upper surface of the gate conductor 12 of the gate structure 10.

Although not depicted in FIG. 1, in addition to field effect transistors, the subsequently formed nickel monosilicide interconnect can provide electrical communication to any semiconductor device including, but not limited to, bipolar junction transistors (BJT) and schottky barrier type semiconductor devices. Further, the subsequently formed nickel monosilicide may also provide electrical contact to a memory device. A memory device is a structure in which the electrical state thereof can be altered and then retained in the altered state, in this way a bit of information can be stored. Examples of memory devices include dynamic random access memory (DRAM) devices, embedded dynamic random access memory (eDRAM) devices, flash memory devices and combinations thereof.

FIGS. 2A and 2B depicts forming a silicon-containing layer 25 on an upper surface of gate structure 10 of a semiconductor device 100. In this embodiment, the silicon-containing layer 25 is a separately deposited layer than the gate conductor 12, and provides the semiconductor-containing surface from which the stabilized nickel monosilicide is to be subsequently formed. In one embodiment, the silicon-containing layer 25 has the geometry of an interconnect line that is in electrical communication with the gate conductor 12. “Electrical communication” as used herein means that the conductivity of the connection between the at least one semiconductor device 100 and the subsequently formed nickel monosilicide interconnect has a room temperature conductivity of greater than 10⁻⁸(Ω-m)⁻¹. Although not depicted in FIGS. 2A and 2B, in the embodiments, in which the subsequently formed nickel monosilicide is not an interconnect line, the silicon-containing surface may be the upper surface of the gate conductor 12 and/or the upper surface of a silicon-containing source and/or drain region 15, 20.

The silicon-containing layer 25 may be composed of any silicon-containing material. For example, the silicon-containing material may include, but is not limited to, silicon (including crystalline silicon), Si:C (e.g., carbon-doped crystalline Si), silicon germanium (SiGe) and SiGeC (e.g., carbon-doped crystalline SiGe). In one example, the silicon-containing layer 25 is composed of polysilicon. The silicon-containing layer 25 may be deposited using chemical vapor deposition (CVD). Chemical vapor deposition (CVD) is a deposition process in which a deposited species is formed as a result of chemical reaction between gaseous reactants at greater than room temperature (e.g. 25° C. to 900° C.), wherein solid product of the reaction is deposited on the surface on which a film, coating, or layer of the solid product is to be formed. Variations of CVD processes include, but not limited to, Atmospheric Pressure CVD (APCVD), Low Pressure CVD (LPCVD) and Plasma Enhanced CVD (EPCVD), Metal-Organic CVD (MOCVD) and combinations thereof may also be employed. Other deposition methods that are suitable for depositing the silicon-containing layer 25 include, but are not limited to, spinning from solution, spraying from solution, and evaporation. The thickness of the silicon-containing layer 25 may range from 1 nm to 70 nm. In one embodiment, the thickness of the silicon-containing layer 25 ranges from 25 nm to 50 nm.

In the embodiment that is depicted in FIG. 2A, the silicon-containing layer 25 is deposited and then patterned and etched to provide the geometry of an interconnect line. Following patterning and etching, the silicon-containing layer 25 is doped with a stabilizing dopant, such as carbon.

FIG. 2B depicts one embodiment, in which prior to patterning and etching the silicon-containing layer 25, the silicon-containing layer 25 is doped with a stabilizing dopant. A “stabilizing dopant” is a dopant that reduces the agglomeration of nickel monosilicide alloys at temperatures greater than 400° C. In some instances, agglomeration is a morphology change from a relatively smooth film to one that substantially roughens at the surface/interface starting at grain boundaries causing the resistivity to increase up to the point of a discontinuous film. By “reducing the agglomeration” of nickel monosilicide it is meant that the degree of agglomeration that is present in the nickel monosilicide that is doped with the stabilizing dopant is reduced in comparison to the agglomeration that occurs in nickel monosilicide that does not include the stabilizing dopant. In one example, the stabilizing dopant is carbon.

The silicon-containing layer 25 may be ion implanted 30a with carbon. Ion implantation includes ionizing the atoms to be implanted (dopant species), accelerating the dopant species in an electric field, and directing the dopant species toward the surface to be implanted. The depth of the ion implantation is typically determined by the dopant species and the implant energy. In one embodiment, in which the stabilizing dopant is carbon, the carbon may be implanted into the silicon-containing layer with a dose ranging from 5×10¹² atoms/cm² to 5×10¹⁶ atoms/cm². In another embodiment, the carbon may be implanted into the silicon-containing layer with a dose ranging from 5×10¹³ atoms/cm² to 5×10¹⁵ atoms/cm². In one example, the silicon-containing layer is implanted with a dose of 5×10¹⁴ atoms/cm². The carbon dopant is typically implanted at an energy from 0.1 keV to about 10 keV. In another embodiment, the ions are implanted at an energy from about 3 keV to about 6 keV. The implant is typically performed at a semiconductor substrate 5 temperature from about room temperature (25° C.) to about 200° C. Note that the ion dose may vary depending on the specific ion being implanted.

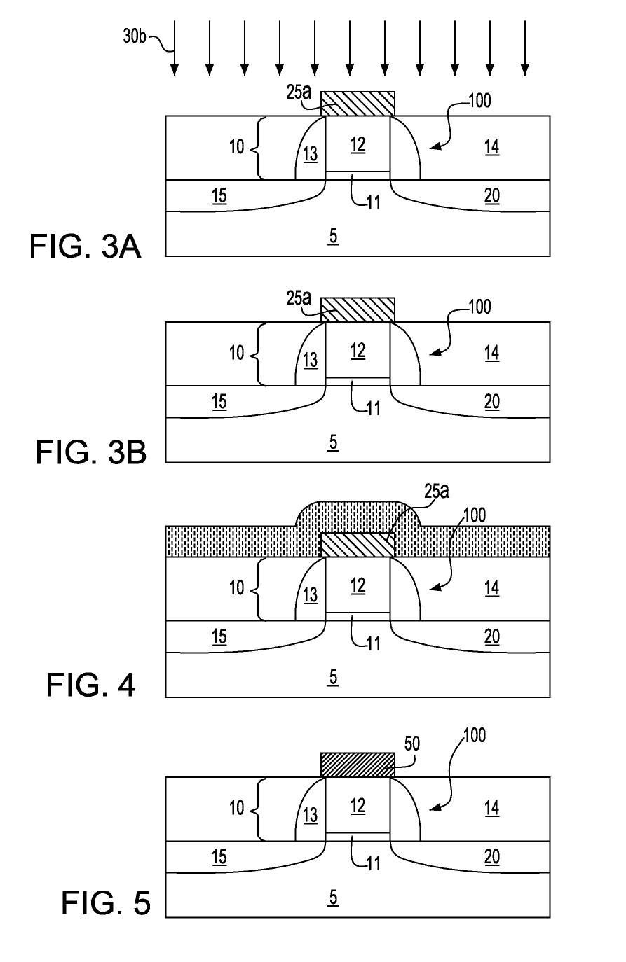

FIG. 3A depicts patterning and etching the silicon-containing layer 25 depicted in FIG. 2A, and doping the patterned silicon-containing layer 25a with a stabilizing dopant. The silicon-containing layer 25 may be patterned and etched to provide the geometry of an interconnect line that is in electrical communication with the gate conductor 12 of the gate structure 10. Specifically, a pattern is produced by applying a photoresist to the surface to be etched, exposing the photoresist to a pattern of radiation, and then developing the pattern into the photoresist utilizing a resist developer.

Once the patterning of the photoresist is completed, the sections covered by the photoresist are protected while the exposed regions are removed using a selective etching process that removes the unprotected regions. As used herein, the term “selective” in reference to a material removal process denotes that the rate of material removal for a first material is greater than the rate of removal for at least another material of the structure to which the material removal process is being applied. In one embodiment, the selective etch process may include an anisotropic etch. An anisotropic etch proces is a material removal process in which the etch rate in the direction normal to the surface to be etched is greater than in the direction parallel to the surface to be etched. The anisotropic etch may include reactive-ion etching (RIE). Reactive Ion Etching (ME) is a form of plasma etching in which during etching the surface to be etched is placed on the RF powered electrode. Moreover, during ME the surface to be etched takes on a potential that accelerates the etching species extracted from a plasma toward the surface, in which the chemical etching reaction is taking place in the direction normal to the surface. Other examples of anisotropic etching that can be used at this point of the present method include ion beam etching, plasma etching or laser ablation. Following etching to remove the exposed portions of the silicon-containing layer 25, the photoresist is removed. The photoresist may be removed using a chemical strip, a selective etch or oxygen ashing.

Following the patterning and etching of the silicon-containing layer 25, the remaining portion of the silicon-containing layer 25a has the geometry of an interconnect line to the gate conductor 12 of the gate structure 10. In one embodiment, the interconnect line, i.e., remaining portion of the silicon-containing layer 25a, has a line width of less than 40 nm. In another embodiment, the interconnect line has a line width of less than 30 nm, e.g., a line width ranging from 1 nm to 30 nm. In yet another embodiment, the line width is less than 25 nm, e.g., a line width ranging from 10 nm to 25 nm. In one embodiment, the line length of the interconnect line is greater than 100 microns, e.g., 100 microns to 1000 microns. In another embodiment, the line length ranges from 0.02 microns to 100 microns. The cross-sectional area of the remaming portion of the silicon-containing layer 25a may range from 2×10¹⁴ cm² to 3.2×10⁻¹¹ cm². In another embodiment, the cross-sectional area of the remaming portion of the silicon-containing layer 25a may range from 2×10⁻¹² cm² to 1.3×10⁻¹¹ cm².

Still referring to FIG. 3A, following patterning and etching of the semiconductor-containing layer, the remaining portion of the semiconductor-containing layer 25a is doped with a stabilizing dopant. In one example, the stabilizing dopant is carbon, which may be introduced to the remaining portion of the semiconductor-containing layer 25a using ion implantation 30b. It is noted that the doping of the remaining portion of the silicon-containing layer 25a with a stabilizing dopant, e.g., carbon, is similar to the doping of the silicon-containing layer 25 with a stabilizing dopant that is described above with reference to FIG. 2B. Therefore, the description of the doping of the semiconductor-containing layer 25 with the stabilizing dopant that is described above with reference to FIG. 2A is suitable for the doping of the remaining portion of the semiconductor-containing layer 25a that is depcited in FIG. 3A.

At this stage of the present method, and in the embodiments in which the stabilizing dopant is carbon, the concentration of carbon dopant in the silicon-containing layer 25 may range from 1×10¹⁸ dopant atoms/cm³ to 1×10²² dopant atoms/cm³. In one embodiment, the concentration of carbon dopant in the silicon-containing layer 25 may range from 1×10¹⁹ dopant atoms/cm³ to 1×10²¹ dopant atoms/cm³.

FIG. 3B depicts patterning and etching the silicon-containing layer 25 depicted in FIG. 2B. In one embodiment, the silicon-containing layer is patterned and etched, wherein the remaining portion of the silicon-containing layer 25a provides the geometry of the interconnect line, which is subsquently processed to be composed of thermally stabilized nickel monosilicide, e.g., a carbon doped nickel monosilicide. The interconnect line provides electrical communication to the gate conductor 12 of the gate structure 10. The patterning and etching of the silicon-containing layer that is depicted in FIG. 3B is similar to the patterning and etching that results in the remaining portion of the silicon containing layer 25a that is depcited in FIG. 3A. Therefore, the description of the patterning and etching the semiconductor-containing layer that is described above with reference to FIG. 3A is suitable for etching the semiconductor-containing layer to provide the remaining portion of the semiconductor-containing layer 25a that is depcited in FIG. 3B.

FIG. 4 depicts depositing a nickel-containing layer 30 on the upper surface of the structures depicted in FIGS. 3A and 3B. At least a portion of the nickel-containing layer 30 is in direct contact with a remaining portion of the silicon-containing layer 25a. The nickel-containing layer 30 may be composed of nickel or nickel alloyed with at least one of platinum (Pt), palladium (Pd), rhodium (Rh) and rhenium (Re). Platinum (Pt), palladium (Pd), rhodium (Rh) and rhenium (Re) as alloying elements may be present in as much as 40% for the total alloying element content of the nickel containing layer, in which the alloying elements may individually be present amounts ranging from 0.1% to 10%.

In one embodiment, the nickel-containing layer 30 includes a nickel content of about 50 at. % or greater. In another embodiment, the nickel content of the nickel-containing layer 30 ranges from 60 at. % to 99.6 at %. In yet another embodiment, the nickel content of the nickel-containing layer 30 ranges from 90 at. % or 99 at %. In one example, the nickel-containing layer 30 is composed of substantially 100% nickel. By “substantially” it is meant that a nickel-containing layer 30 that is intended to be 100% nickel may have incidental impurities that are present therein. By incidental impurities, it is meant that some elements included in the nickel-containing layer 30 are the result of impurities from processing, such as impurities introduced by the atmosphere.

The nickel-containing layer 30 may be deposited using a deposition process including, for example, chemical vapor deposition, physical vapor deposition, atomic layer deposition, electrodeposition and electroless deposition. In one embodiment, the nickel-containing layer 30 may be deposited using a physical vapor deposition method, such as plating or sputtering. Sputtering includes applying high energy particles to strike a solid slab of a target material composed of the material to be deposited, in which the high energy particles physically dislodge atoms of material from the target material to be deposited on at least the remaining portion of the silicon-containing layer 25a. In one example, the ion energies of the high-energy particles, e.g., positive ions from an argon gas flow discharge range from 500 eV to 5,000 eV. In another embodiment, the ion energies of the high-energy particles range from 1,500 eV to 4,500 eV. In one embodiment, a sputtering deposition process for depositing nickel for the nickel-containing layer 30 includes applying high energy particles to strike a solid slab of a nickel target material, in which the high energy particles physically dislodge atoms of nickel to be deposited on at the semiconductor-containing layer 25. The sputtered atoms of nickel typically migrate through a vacuum and deposit on the silicon-containing layer 25.

Typically, the nickel-containing layer 30 has a thickness ranging from 1 nm to 40 nm. In another embodiment, the nickel-containing layer 30 has a thickness ranging from 5 nm to 25 nm. In yet another embodiment, the nickel-containing layer 30 has a thickness ranging from 15 nm to 30 nm.

FIG. 5 depicts one embodiment of intermixing the nickel-containing layer 30 and the silicon-containing layer 25 that has been doped with the stabilizing dopant, e.g., carbon, to provide a nickel monosilicide layer 50. In one embodiment, the intermixing of the nickel-containing layer 30 and the remaining portion of the silicon-containing layer 25a including the stabilizing dopant is provided by an annealing process step. The annealing process step is performed at a temperature that is effective in intermixing at least a portion of the silicon-containing layer 25a, and at least a portion of the nickel-containing layer 30 to provide a mixture of the two material layers, i.e., a nickel silicon mixture. Often the thermal anneal is conducted using Rapid Thermal Anneal (RTA).

In one embodiment, the annealing process step includes a thermal dose ranging from 300° C. to 650° C., for a time period ranging from 10 seconds to 30 minutes. In another embodiment, the thermal dose includes an annealing temperature ranging from 350° C. to 600° C. In yet another embodiment, the thermal dose includes an annealing temperature ranging from 375° C. to 575° C.

In one embodiment, in which the stabilizing dopant is carbon, the carbon doped nickel monosilicide 50 produced by the above method typically includes nickel content ranging from 45 at. % to 55 at. %, a silicon content ranging from 45 at. % to 55 at. %, and a carbon content ranging from 0.01 at. % to 5 at. %. In another embodiment, the carbon doped nickel monosilicide includes nickel content ranging from 48 at. % to 52 at. %, a silicon content ranging from 48 at. % to 52 at. %, and a carbon content ranging from 0.01 at. % to 0.5 at. %. In yet another embodiment, the carbon doped nickel monosilicide includes nickel content ranging from 47 at. % to 53 at. %, a silicon content ranging from 47 at. % to 53 at. %, and a carbon content ranging from 0.01 at. % to 1.0 at. %. Platinum (Pt), palladium (Pd), rhodium (Rh) and rhenium (Re) may be present in the carbon doped nickel monosilicide 50 as an alloying element. Incidental impurities may be present in the carbon doped nickel monosilicide 50 in up to 0.4 at. %.

Following the formation of the nickel monosilicide 50, e.g., carbon doped nickel monosilicide, the unreacted remaining portions of the nickel-containing layer 30, such as the portions that are overlying the dielectric-containing materials, such as the interlevel dielectric 14 and the sidewall spacers 13, are removed using an etch process, such as wet etching, reactive-ion etching (RIE), ion beam etching, or plasma etching. The resultant nickel monosilicide 50, e.g., carbon doped nickel monosilicide, is more resistive to etch processing steps when compared to the non-reacted metal layer that is removed during the etching step. The final thickness of the nickel monosilicide 50 ranges from about 2 nm to about 85 nm.

Still referring to FIG. 5, in one embodiment, the above-described method provides a semiconductor device 100 including a non-agglomerated nickel monosilicide contact (nickel monosilicide 50) including a carbon interstitial dopant present in a concentration ranging from 1×10¹⁹ atoms/cm³ to 1×10²¹ atoms/cm³ wherein the carbon interstitial dopant increases the thermal stability of the nickel monosilicide contact. By “interstitial dopant” it is meant that the carbon dopant is not an element of the crystal lattice structure of the nickel monosilicide, but instead the carbon is present between lattice sites, i.e., lattice atoms.

In one embodiment, the nickel monosilicide, e.g., carbon doped nickel monosilicide, has a resistance of less than 400 Ω/μm for line widths of greater than 20 nm when exposed to temperatures of up to 800° C. In another embodiment, the carbon doped nickel monosilicide has a resistance of less than 200 Ω/μm for line widths of greater than 25 nm when exposed to temperatures ranging from 400° C. to 800° C. The low resistance of the carbon doped nickel monosilicide at high temperature is indicative of thermal stability. In addition to thermal stability, the stabilizing dopant, e.g., carbon, reduces line edge and surface roughness. Although not wishing to be bound by theory, it is believe that the stabilizing dopant, e.g., carbon, reduces the mobility of nickel and silicon, therefore providing increased thermal stability and increased resistance to agglomeration.

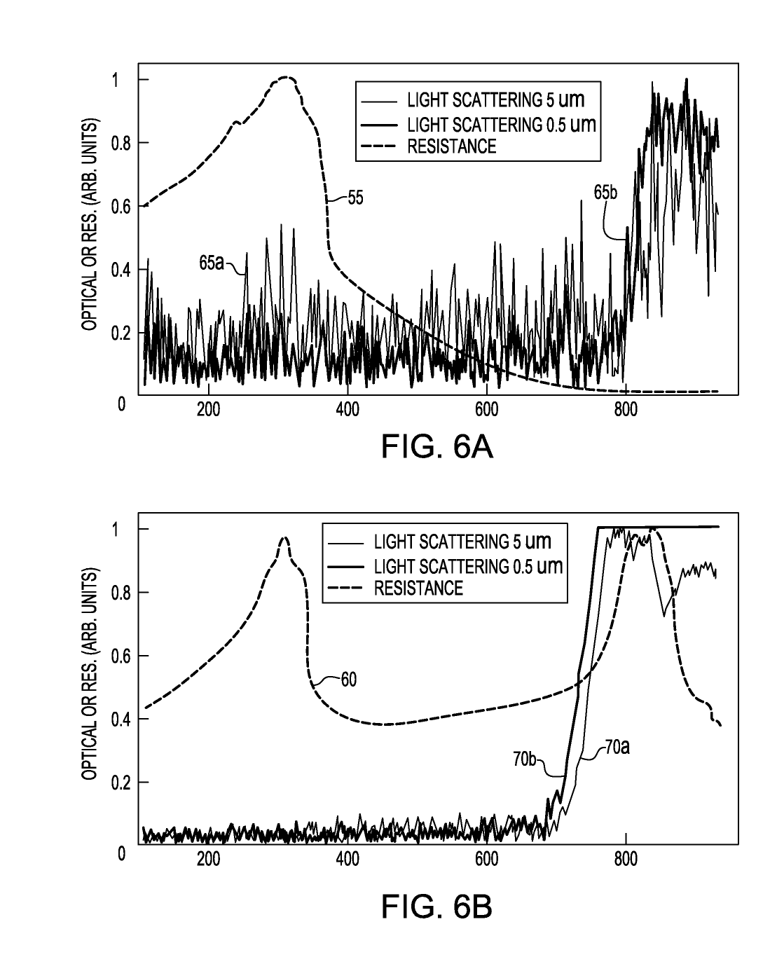

FIG. 6A is a plot of the resistance and the optical scattering of a carbon doped nickel monosilicide layer as a function of temperature. The example utilized to provide the data depicted in FIG. 6A was a blanket film with carbon implanted in the silicon at a dose of 5×10¹⁴ atoms/cm². The carbon doped nickel monosilicide included a nickel content ranging from 48 at. % to 52 at. %, a silicon content ranging from 48 at. % to 52 at. %, and a carbon content ranging from 0.01 at. % to 0.5 at. %.

As illustrated in FIG. 6A, the carbon doped nickel monosilicide decreases in resistance (plot 55) with increasing temperature at greater than 400° C. The light scattering measurement is a characterization of the surface of the carbon doped nickel monosilicide. A structure having a low optical scattering measurement has a smooth surface. A structure that has an agglomerated surface has a high optical scattering measurement. As illustrated by FIG. 6A, there is little change in the light scattering measurements (plot 65a and 65b) taken from the surface of the carbon doped nickel monosilicide until greater than 800° C. Plot 65a is a plot of the lateral length scale of the roughness measured at 5 μm. Plot 65b is a plot of the lateral length scale of the roughness measured at 0.5 μm. The plots are in arbitrary units with the highest intensity normalized to one. At temperatures greater than 800° C., the optical scattering increases.

FIG. 6B is a plot of the resistance and the optical scattering of a comparative example of a nickel monosilicide layer that is not doped with carbon as a function of temperature. Similar to the example utilized to provide the data in FIG. 6A, the data plotted in FIG. 6B was a blanket film of silicon having the same dimensions as the example used to provide the data in FIG. 6A. The nickel monosilicide did not include a carbon dopant and was composed of 50 at. % silicon and 56 at % nickel. The resistance measurements (plot 60) for the comparative example from 400° C. to 800° C. were greater than the resistance measurements taken from the carbon doped nickel monosilicide. Also the resistance measurements (plot 60) for the comparative example included a resistance peak beginning at approximately 800° C. Light scattering measurements (plots 70a and 70b) taken from the comparative example indicate that the surface roughness of the nickel monosilicide that does not include the carbon dopant increases at temperatures greater than 675° C. Plot 70a is a plot of the lateral length scale of the roughness measured at 5 μm. Plot 70b is a plot of the lateral length scale of the roughness measured at 0.5 μM. The plots are in arbitrary units with the highest intensity normalized to one. Both the increases in resistance and optical scattering in the comparative example are indicative of low thermal stability.

While this invention has been particularly shown and described with respect to preferred embodiments thereof, it will be understood by those skilled in the art that the foregoing and other changes in forms and details may be made without departing from the spirit and scope of the present invention. It is therefore intended that the present invention not be limited to the exact forms and details described and illustrated, but fall within the scope of the appended claims.

What is claimed is:

1. A method of forming a nickel semiconductor alloy compound comprising:
introducing a stabilizing dopant to a silicon-containing surface;
forming a nickel-containing layer on the silicon-containing surface; and
intermixing the nickel-containing surface and the silicon-containing surface layer to provide a nickel monosilicide layer, wherein the nickel monosilicide layer has a resistance of less than 400 Ω/μm for line widths of greater than 20 nm when exposed to temperatures of up to 800° C.

2. The method of claim 1, wherein the silicon-containing surface is polysilicon.

3. The method of claim 1, wherein the silicon-containing surface is patterned and etched to provide a line structure before the stabilizing dopant is introduced to the silicon-containing surface, or the stabilizing dopant is introduced to the silicon-containing surface before the silicon-containing surface is patterned and etched to provide the line structure.

4. The method of claim 3, wherein the line structure has a line length of 0.02 microns or greater, and the cross-sectional area of the line structure ranges from 2×10⁻¹⁴ cm² to 3.2×10⁻¹¹ cm².

5. The method of claim 1, wherein the introducing of the stabilizing dopant comprises ion implantation.

6. The method of claim 5, wherein the stabilizing dopant is carbon.

7. The method of claim 6, wherein the carbon is ion implanted at 5×10¹³ atoms/cm² to 5×10¹⁵ atoms/cm².

8. The method of claim 1, wherein the nickel-containing layer comprises nickel or nickel alloyed with at least one of platinum (Pt), palladium (Pd), rhodium (Rh) and rhenium (Re).

9. The method of claim 1, wherein the nickel-containing layer is deposited by plating, sputtering, chemical vapor deposition or atomic layer deposition.

10. The method of claim 1, wherein the alloying of the nickel-containing surface and the silicon-containing surface layer comprise annealing at a temperature ranging from 350° C. to 600° C.

11. The method of claim 1 further comprising removing unreacted nickel-containing material following the formation of the nickel monosilicide layer with a selective etch.

12. A method of forming nickel semiconductor alloy comprising
implanting carbon into a silicon-containing surface;
forming a nickel-containing layer on the silicon-containing surface; and
intermixing the nickel-containing surface and the silicon-containing surface layer to provide a nickel monosilicide layer.

13. The method of claim 12, wherein the silicon-containing surface is polysilicon.

14. The method of claim 12, wherein the line structure has a line length of 0.02 microns or greater, and the cross-sectional area of the line structure ranges from 2×10⁻¹⁴ cm² to 3.2×10⁻¹¹ cm².

15. The method of claim 12, wherein the carbon is ion implanted at 5×10¹³ atoms/cm² to 5×10¹⁵ atoms/cm².

16. The method of claim 12, wherein the nickel-containing layer comprises nickel or nickel alloyed with at least one of platinum (Pt), palladium (Pd), rhodium (Rh) and rhenium (Re).

17. The method of claim 12, wherein the nickel-containing layer is deposited by plating, sputtering, chemical vapor deposition or atomic layer deposition.

18. The method of claim 12, wherein the alloying of the nickel-containing surface and the silicon-containing surface layer comprise annealing at a temperature ranging from 350° C. to 600° C.

19. A semiconductor device comprising:
a Si-containing material; and
a non-agglomerated nickel monosilicide contact located on a portion of said Si-containing material, wherein said non-agglomerated nickel monosilicide contact comprises a carbon interstitial dopant present in a concentration ranging from 1×10¹⁹ atoms/cm³ to 1×10²¹ atoms/cm³.

20. The semiconductor device of claim 19, wherein the non-agglomerated nickel monosilicide contact is an interconnect line having a line length of 0.02 microns or greater, and the cross-sectional area ranging from 2×10⁻¹⁴ cm² to 3×10⁻¹¹ cm², wherein the resistance of the interconnect line is less than 400 Ω/μm for linewidths greater than 20 nm when exposed to temperatures of up to 800° C.
